(19) United States
(12) Patent Application Publication
(10) Pub. No.: US 2024/0426717 A1
(43) Pub. Date: Dec. 26, 2024

(54) Method and System for Sample Preparation

(71) Applicant: FEI Company, Hillsboro, OR (US)

(72) Inventors: Jakub Kuba, Hillsboro, OR (US); Pavel Krepelka, Brno (CZ); Miloš Hovorka, Brno (CZ); John Mitchels, Brno (CZ); Radim Kríž, Slapanice (CZ); Matej Dolník, Brno (CZ)

(21) Appl. No.: 18/731,712

(22) Filed: Jun. 3, 2024

Related U.S. Application Data
(60) Provisional application No. 63/471,208, filed on Jun. 5, 2023.

(51) Int. Cl. G01N 1/28; G06T 7/73; G06V 10/25; G06V 20/69; H01J 37/20

(52) U.S. Cl. CPC G01N 1/286; G06T 7/74; G06V 10/25; G06V 20/693; H01J 37/20; G06T 2207/10056; G06T 2207/10064; G06T 2207/30024; H01J 2237/2067

(57) ABSTRACT

A sample is milled to expose the region of interest (ROI) within the sample, while being held by a sample stage in a microscopy system. The sample is milled based on the ROI location determined with sample images acquired with light beam irradiating from different axes. The sample images are acquired while the sample is held using the same sample stage for milling.

### CROSS-REFERENCE TO RELATED APPLICATIONS

This application claims the benefit under 35 U.S.C. § 119 (e) of U.S. Provisional Application No. 63/471,208, filed Jun. 5, 2023. The entire contents of the aforementioned application is incorporated by reference herein.

### FIELD OF THE INVENTION

The present description relates generally to methods and systems for analyzing a sample, and more particularly, to preparing a sample for inspection under a charged particle microscope using optical imaging.

### SUMMARY

In one embodiment, a method for preparing a sample comprises irradiating a sample held by a sample stage along a first axis relative to the sample with a light beam and acquiring at least a first sample image by detecting emitted photons from the sample along the first axis; irradiating the sample along a second axis relative to the sample with the light beam and acquiring at least a second sample image by detecting emitted photons from the sample along the second axis; determining location of a region of interest (ROI) within the sample based on the first sample image and the second sample image; and milling the sample held by the sample stage based on the location of the ROI.

In another embodiment, a microscopy system comprises a sample chamber; a sample stage positioned in the sample chamber; a light source for generating a light beam; an objective, a detector for detecting emitted photons from the sample passing through the objective; a milling source for generating a milling beam; and a controller including a processor and a non-transitory memory for storing computer readable instructions, by executing the computer readable instructions in the processor, the microscopy system is configured to: irradiate, via the objective, a sample held by the sample stage along a first axis relative to the sample with the light beam and acquire at least a first sample image via the detector; irradiate, via the objective, the sample along a second axis relative to the sample with the light beam and acquire at least a second sample image via the detector; determine a location of a region of interest (ROI) within the sample based on the first sample image and the second sample image; and mill the sample held by the sample stage with the milling beam based on the location of the ROI.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

FIG. 1 illustrates an example of a microscopy system.

FIG. 2 is an image showing a sample stage positioned in a sample chamber of the microscopy system.

FIG. 3 is a flowchart of a method for preparing a sample.

FIGS. 4A-4B illustrate one example of acquiring sample images.

FIG. 5 illustrates another example of acquiring sample images.

Like reference numerals refer to corresponding parts throughout the several views of the drawings.

### DETAILED DESCRIPTION

The following description relates to systems and methods for sample preparation, in particular, for preparing a frozen biological sample being imaged with a transmission electron microscope (TEM). TEM imaging requires a thin sample, such as a lamella, to allow electrons to transmit through. The lamella may be prepared by milling or micromachining a bulk sample using a laser and/or a charged particle beam. The region of interest (ROI) embedded in the bulk sample needs to be accurately identified and localized to ensure that the prepared lamella includes the ROI. One way to identify and localize the ROI is using fluorescence optical microscopy (FM). The fluorescence data may include multiple 2D scans, which can comprise of a lateral (tile set) or axial (stack) series. However, accurately localizing ROI in the 3D bulk sample based on the fluorescence data may be challenging, because the lateral resolution of the fluorescence imaging system is higher than its axial resolution. Though the ROI location in the axial direction of the incident beam can be estimated based on the intensity of the fluorescent signal or by optical sectioning (acquiring multiple 2D fluorescent images at various imaging depth-stacks), the axial localization accuracy is intrinsically limited by the lower axial resolution of the imaging system. Further, FM may have limited imaging depth for mapping the entire ROI. There is a need to accurately and quickly preparing the sample for inspection under a charged particle microscope. For example, there is a need to accurately and quickly localize the ROI, and prepare the sample (such as by milling) to form a lamella so that the ROI may be further analyzed under a charged particle microscope (such as TEM).

The above issues may be addressed by determining ROI location based on optical images of the sample acquired from different light incidence angles (i.e., different views/axes) relative to the sample surface. For example, a first sample image is acquired by irradiating the sample along a first axis and a second sample image is acquired by irradiating the sample along a second, different axis. In other words, the first sample image is acquired by irradiating the sample at a first incidence angle and the second sample image is acquired by irradiating the sample at a second incidence angle. The sample image is acquired by collecting/detecting photons emitted from the sample along the same optical axis of its corresponding irradiation beam. In one example, the sample image is acquired in a reflection mode, wherein the same objective is used to focus the irradiation beam on the sample and collect photons emitted from the sample responsive to the irradiation. A ROI of the sample is imaged in both the first and second images. The location of the ROI may be determined based on the first and second sample images. The sample may then be milled or micromachined based on the location of the ROI. By locating the ROI based on the sample images acquired from different incidence angles, the ROI may be localized at a higher spatial resolution in any direction comparing to the axial resolution of the microscopy system. The sample is imaged and milled while being held on the same sample stage in the vacuum chamber. By imaging and milling in the vacuum chamber, the sample may be processed/milled without breaking the vacuum. The milling may be performed by a milling beam generated from a milling source. The milling beam may be a laser beam or a charged particle beam. The milling source may be laser source, electron source, or ion source. By using the same sample stage for both sample imaging and milling, ROI location and the milling location can be represented using the same coordinate system. In some examples, the coordinate system may be the sample stage coordinate system. As such, conversion between different coordinate systems may be avoided. In some examples, the ROI may include one or more targets and fiducials, the target location may be represented based on the coordinate system defined by the fiducials, such as the target's position relative to the fiducials.

The ROI may be one or more regions within the sample. The ROI may include one or more targets to be inspected or analyzed, as well as one or more internal and/or external fiducials. For example, the fiducials may be fluorescent beads embedded in the sample. The target may be a part of a cell, such as the mitochondria or the cell membrane. In other examples, the fiducials may present outside the sample volume. For example, the sample is positioned on a TEM grid. One or more fluorescent beads may be positioned on the surface or next to the cell on supporting membrane. In another example, the fiducial may be dirt external to the cell. The sample image may be fluorescent images including wide field, reflection or confocal fluorescent images. Fluorescent signals from the ROI may be generated due to intrinsic or extrinsic fluorescence. The location of the ROI may be presented by one or more 3D coordinates. Determining the location of the ROI includes mapping the ROI within the sample. In one example, the contour or boundary of the target may be delineated based on the 3D coordinates. In another example, the geometric center of the target may be determined based on the 3D coordinates.

Determining the location of the ROI based on the first and second sample images may include determining the first coordinates of the ROI in the first sample image, and the second coordinates of the ROI in the second sample image. The first coordinates and the second coordinates are 3D coordinates (i.e., including X, Y, and Z components). The first and second coordinates may be determined further based on the signal intensity. For example, the first and second coordinates may include the location of the ROI in a first sample plane and a second sample plane, respectively. The first sample plane and the second sample plane orthogonal to the first and second axes, respectively. The locations of the first and second sample planes may be determined based on the intensity of the fluorescent signal. The first coordinates and the second coordinates may be relative coordinates, such as coordinates relative to the fiducials. The relative coordinates may be converted to sample stage coordinates through a correlation step. For example, in the correlation step, common features in a first image corresponding to the relative coordinates and a second image corresponding to the sample stage coordinates may be used for converting the coordinates.

Determining the location of the ROI based on the first and second sample images may include determining the ROI location based on the orientations of the first and second axes relative to the sample stage. For example, coordinates of the ROI in planes orthogonal to the first axis are determined based on the first image, and coordinates of the ROI in planes orthogonal to the second axis are determined based on the second image. As such, the ROI is localized utilizing the higher lateral resolution of imaging system. The ROI is localized at a higher spatial resolution than the axial resolution of the optical imaging system.

Determining the location of the ROI based on the first and second sample images may include merging the first and the second sample images, and determining the ROI location based on the merged sample image. The first and second sample images are 2D images, while the merged image may be a 3D sample image. The first and second sample images may be merged based on their own coordinates (such as stage coordinates), intrinsic/extrinsic markers or sample features, or other types of images acquired together with the first and second sample images. Comparing to determining the first and second coordinates of the ROI in the first and second images, merging the sample images can be computationally intense and increasing the overall sample preparation duration.

In one example, the sample is irradiated along the first and second axes by tilting the sample via actuating the sample stage. The objective of the optical microscope may maintain a fixed position relative to the sample chamber. As such, acquisition of the first and second images is enabled by the sample stage. The first and second directions may be of the same angle relative to the normal (Z direction) of the sample stage. Based on the first and the second sample images, location of the ROI in a third direction (such as the Z direction of the sample stage) can be determined with a better resolution comparing to the axial resolution of the beam alone.

In some examples, multiple first sample images and multiple second sample images are acquired at different imaging depths along the first and second axes, respectively. Based on the stack of sample images, location of multiple ROIs or large volume ROIs can be determined. Further, the ROI location along the first and the second axes can be more accurately determined, for example, based on signal strength.

The ROI location determined from the sample images are represented using the sample stage's coordinate system. The sample may then be milled using a light beam or a charged particle beam. The milling may be performed while the sample is held by the same sample stage for optical imaging. The sample stage is positioned in a sample chamber under vacuum. The optical imaging and the imaging/milling with the charged particles can be performed without moving the sample outside of the sample chamber. The milling may be performed according to a milling box placed based on the determined ROI location. The sample may be milled from one or multiple directions to remove materials adjacent or around the ROI. The sample may be milled to form a lamella.

In some examples, one or more third sample images may be acquired by irradiating the sample from a third direction, different from the first and second directions. The ROI location may be determined or updated based on the third images.

In some examples, after removing materials from the sample by milling, optical sample images may be acquired from the milled sample. By removing materials, signals of ROI in the optical sample images may be stronger, thus ROI location can be more accurately determined. The milling and optical imaging process may be performed iteratively. In some examples, sample images (such as FIB images) may be acquired during the milling. In some examples, the sample may be imaged using a charged particle beam, such as an electron beam after milling the sample. In some examples, in addition to the light optical images, charged particle images, such as SEM/FIB images, of the sample surfaces may be imaged to further confirm, monitor, and determine ROI location in the sample. For example, the SEM/FIB images may be used in addition to the 2D or 3D optical image set to monitor or determine the ROI location in the sample. For example uni-directional optical stacks (e.g., optical stack along a depth direction) could be combined with a FIB view to calculate ROI and/or fiducial positions. In some examples, a stack of sample images may be taken at different imaging depths (or sample depths). The stack images may be acquired by adjusting the focal depth and/or during the process of removing the materials from the sample by milling. The image stack may include optical images or charged particle images, such as SEM or FIB images. One or more artificial marks (fiducials such as beads or ion beam milled structures) may be used for aligning images within a stack. The artificial marks may also be used to cross-correlate the optical images and the charged particle images (such as SEM/FIB images) for locating the ROI. In some examples, 3D image of the sample can be reconstructed from the image stack.

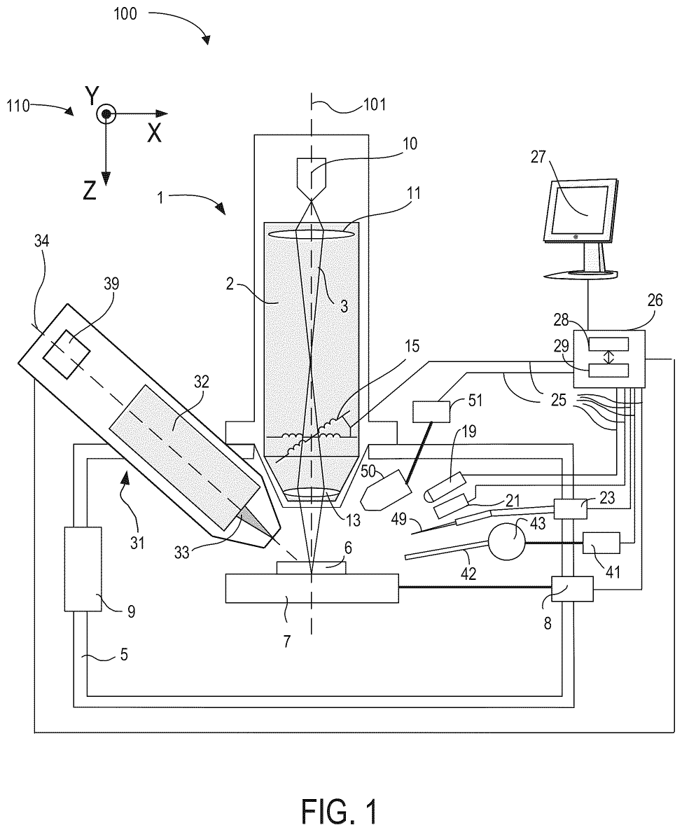

Turning to FIG. 1, FIG. 1 is a highly schematic depiction of an embodiment of a charged particle microscopy (CPM) system in which the present invention may be implemented; more specifically, it shows an embodiment of a FIB-SEM. System coordinates are shown as 110. Microscope 100 comprises an electron-optical column 1, which produces beam 3 of charged particles (in this case, an electron beam) that propagates along an electron-optical axis 101. Electron-optical axis 101 may be aligned with the Z axis of the system. The column 1 is mounted on a vacuum chamber (or sample chamber) 5, which comprises a sample stage 7 and associated actuator(s) 8 for holding/positioning a sample 6. Micro-manipulator 49 may be actuated by actuator 23 for manipulating a sample/specimen, such as a lamella extracted from sample 6. The vacuum chamber 5 is evacuated using vacuum pumps (not depicted). Also depicted is a vacuum port 9, which may be opened to introduce/remove items (components, samples) to/from the interior of vacuum chamber 5. Microscope 100 may comprise a plurality of such ports 9, if desired.

The column 1 comprises an electron source 10 and an illuminator 2. This illuminator 2 comprises lenses 11 and 13 to focus the electron beam 3 onto the sample 6, and a deflection unit 15 (to perform beam steering/scanning of the beam 3). The microscope 100 further comprises a controller/computer processing apparatus 26 for controlling inter alia the deflection unit 15, lenses 11, 13, micro-manipulator 49, and detectors 19, 21, and displaying information gathered from the detectors 19, 21 on a display unit 27.

In addition to the electron column 1 described above, the microscope 100 also comprises an ion-optical column 31. This comprises an ion source 39 and an illuminator 32, and these produce/direct an ion beam 33 along an ion-optical axis 34. To facilitate easy access to the sample, the ion axis 34 is canted relative to the electron axis 101. As hereabove described, such a focused ion beam (FIB) column 31 can, for example, be used to perform processing/machining operations on the sample 6, such as incising, milling, etching, depositing, etc. The ion column 31 can also be used to produce imagery of the sample 6. It should be noted that ion column 31 may be capable of generating various different species of ion at will; accordingly, references to ion beam 33 should not necessarily been seen as specifying a particular species in that beam at any given time—in other words, the beam 33 might comprise ion species A for operation A (such as milling) and ion species B for operation B (such as implanting), where species A and B can be selected from a variety of possible options. The ion source 39 may be a liquid metal ion source or a plasma ion source.

Also illustrated is a Gas Injection System (GIS) 43, which can be used to effect localized injection of precursor gases for the purposes of performing gas-assisted etching or deposition. Such gases can be stored/buffered in a reservoir 41, and can be administered through a narrow nozzle 42, so as to emerge in the vicinity of the intersection of axes 101 and 34, for example.

Microscope 100 may include a laser source (not shown) for directing a laser beam towards the sample. Portions of the sample may be milled or removed using the laser beam. The laser beam may be used also as a source for exciting the fluorescent signal which is captured for images from the views.

The sample may be milled by one or more of the FIB and the laser beam according to a milling box virtually placed by the user or the controller. The milling box defines a 3D region to be milled relative to the sample. The incidence angle of the FIB or laser beam may be also determined while placing the milling box. The 3D region may be defined using the sample stage coordinate system to which the beams (FIB and/or laser beam) can be correlated to.

An optical microscope 50 is positioned within the vacuum chamber 5. The microscope may be a fluorescence microscope, refection microscope, transmitted light or a confocal microscope. The microscope is configured to image the sample 6 held by the sample stage 7. The sample position may be adjusted by operating the sample stage to achieve different incidence angles of the light beam, as well as image different regions of the sample. The imaging depth may be adjusted by adjusting one or more optical elements of the microscope. In one example, all optical elements of the microscope are positioned within the vacuum chamber. In another example, one or more optical elements or components 51 of the microscope are located outside of the vacuum chamber. The optical microscope may be controlled by controller 26 for acquiring images of the sample 6. The optical microscope may contain a camera (pixelated detector in the case wide field scenarios or scanning source with amplified detector in the case of point scanning methods) that can detect light signal from the sample. The excitation source for the optical imaging may be either incorporated into the optical microscope or a part separate from the optical microscope.

The detectors 19 and 21 are chosen from a variety of possible detector types that can be used to examine different types of “stimulated” radiation emanating from the sample 6 in response to irradiation by the (impinging) beam 3 and/or beam 33. Detector 19 may be an X-ray detector, such as Silicon Drift Detector (SDD) or Silicon Lithium (Si(Li)) detector, for example. Detector 21 may be an electron detector in the form of a solid-state photomultiplier (SSPM) or evacuated photomultiplier tube (PMT) for example. This can be used to detect backscattered and/or secondary electrons emanating from the sample. The skilled artisan will understand that many different types of detectors can be chosen in a set-up such as that depicted, including, for example, an annular/segmented detector. By scanning the beam 3 or beam 33 over the sample 6, stimulated radiation—comprising, for example, X-rays, infrared/visible/ultraviolet light, secondary ions, secondary electrons (SEs) and/or backscattered electrons (BSEs)—emanates from the sample. Since such stimulated radiation is position-sensitive (due to said scanning motion), the information obtained from the detectors 19 and 21 will also be position-dependent.

The signals from the detectors 19, 21 and optical microscope 50 pass along control lines (buses) 25, are processed by the controller 26, and displayed on display unit 27. Such processing may include operations such as combining, integrating, subtracting, false coloring, edge enhancing, and other processing known to the skilled artisan. In addition, automated recognition processes may be included in such processing. The controller includes a non-transitory memory 29 for storing computer readable instructions and a processor 28. Methods disclosed herein may be implemented by executing the computer readable instructions in the processor. For example, the controller may control the microscope to image and mill the sample, collect data, and process the collected data. The controller may display the images on the display. The controller may adjust the ion beam energy by adjusting one or more lenses and/or the ion source. The controller may adjust the sample position via the actuator coupled to the sample stage.

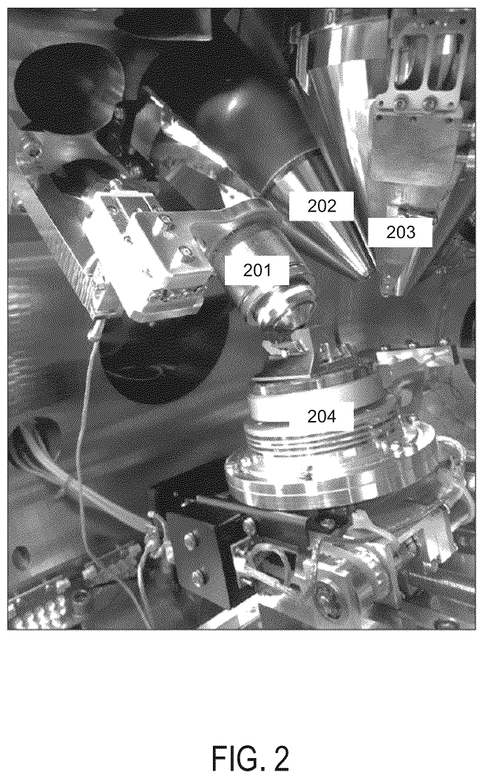

FIG. 2 is a picture of the internal of a vacuum chamber of a charged particle microscopy system. the sample positioned on the sample stage 204 may be imaged or processed by one or more of the FIB formed by the ion-optical column 202 or the electron beam formed by the electron-optical column 203. Fluorescence images may be acquired by an optical microscope including the objective 201. Because the sample is imaged and processed in the same sample chamber while positioned on the sample stage, the same coordinate system maybe used for imaging and the processing.

In some embodiments, the optical microscope may be configured to irradiate the sample from an incidence angle that is different from the incidence angle of the charged particle beam. In one example, the optical microscope is positioned on the same side of the charged particle columns relative to the sample stage. FIGS. 1-2 show the optical microscope positioned above the sample stage. In other words, the optical beam and the charged particle beam are directed towards the sample from the same side (e.g., top side) of the sample. In another example, the optical microscope may be positioned below the sample stage while the charged particle columns are positioned above the sample stage. As such, light beam irradiates the sample from below the sample stage.

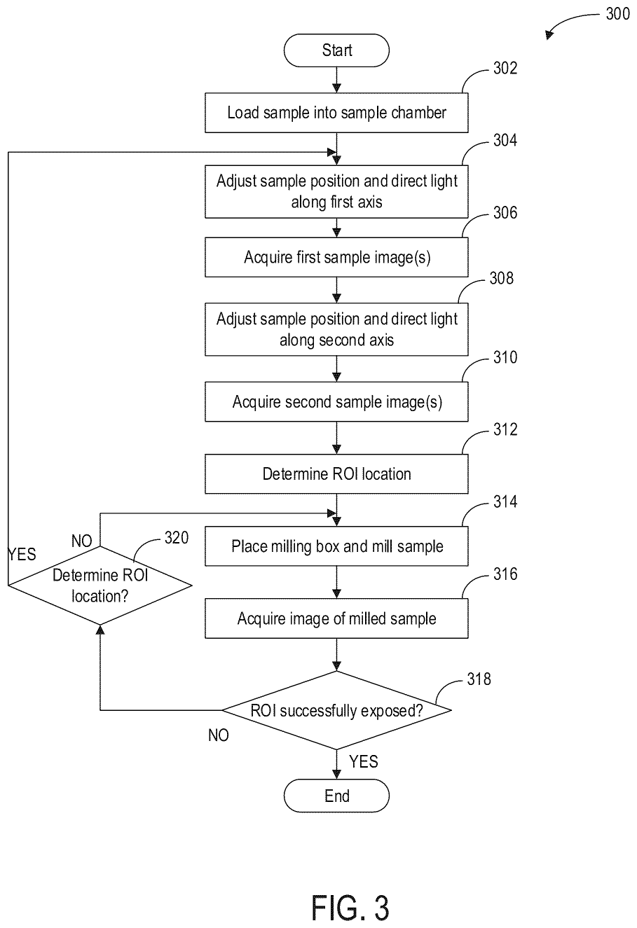

FIG. 3 shows method 300 for preparing a sample by milling the sample and exposing the ROI. The method 300 may be executed using microscope 100 shown in FIG. 1.

At 302, the sample is loaded into the sample chamber. The sample may be loaded into the evacuated sample chamber via a loadlock. Loading the sample include positioning the sample onto the sample stage within the sample chamber. The sample may be positioned based on images from a navigation camera

At 304, the sample position is adjusted so that the light beam is directed along a first light axis towards the sample. One or more first sample images are acquired at 306 responsive to the irradiation of the light beam at 304. The sample position may be adjusted by operating the actuator coupled with the sample stage. The sample may firstly be translated to an imaging location under the optical microscope, and then tilted towards the objective of the optical microscope allowing light beam to image the ROI along the first axis. In one example, the portion of the sample to be imaged may be determined based on the known knowledge of potential locations of the ROI. In another example, series of optical or charged particle images may be acquired to determine the potential locations of the ROI before acquiring the first and second sample images. The acquired first sample images may be a single image or multiple images acquired at various imaging depths.

At 308, the sample position is adjusted so that the light beam is directed along a second axis towards the sample. One or more second sample images are acquired at 310 responsive to the irradiation of the light beam at 308. The ROI is imaged in both the first and second images. The sample stage may be adjusted so that Z-axis of the sample stage is the same angle from the first axis and the second axis.

At 312, location of at least one ROI that is imaged in both the first and second images is determined. In some examples, the ROI may include targets and/or fiducials of the sample. In one example, the first coordinates (x1, y1, z1) of the ROI are determined in the first image, and the second coordinates (x2, y2, z2) of the same ROI are determined in the second image. The third, more accurate coordinates (x3, y3, z3) of the ROI may be determined based on the first and second coordinates. It may also require relative measurements between ROI and fiducial to maintain scale and relative movements.

As such, the location of the ROI is determined based on orientations of the first axis and the second axis. In one example, the location of the ROI in a first plane orthogonal to the first axis is determined based on the first image and the location of the ROI in a second plane orthogonal to the second axis based on the second image.

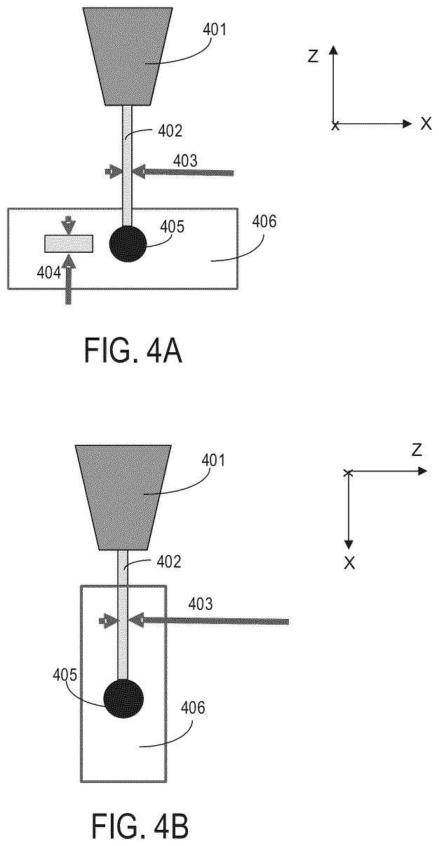

FIGS. 4A-4B illustrate an example of light beam directions relative to sample 406 for acquiring the first and second images. The first image is acquired when sample 406 is irradiated with light beam 402 from the objective 401 along the Z axis of the sample stage, as shown in FIG. 4A. Then, the sample is rotated by 90 degrees, and the second image is acquired when the sample is irradiated with light beam 402 along the X axis of the sample stage. As such, the ROI 405 may be mapped with the higher lateral resolution 403 comparing to the lower axial resolution 404.

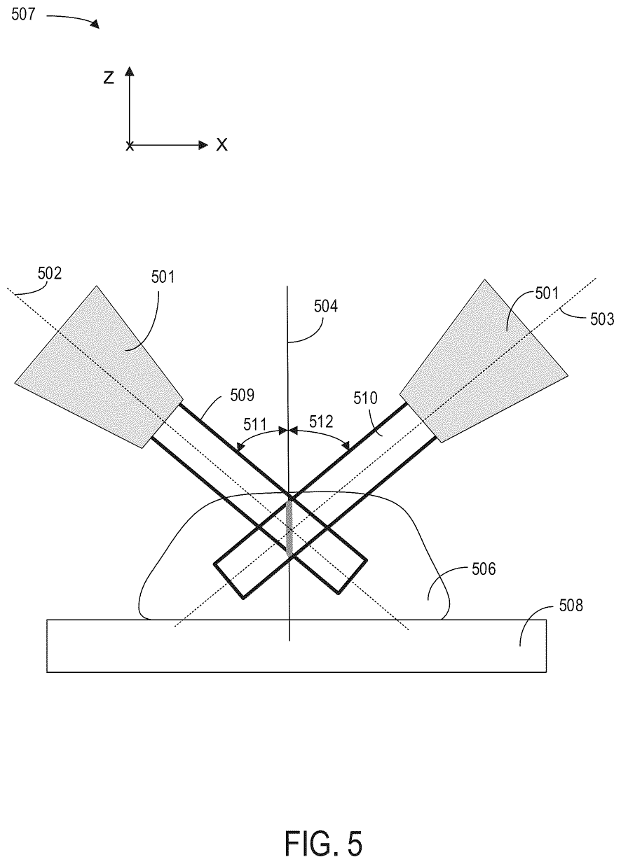

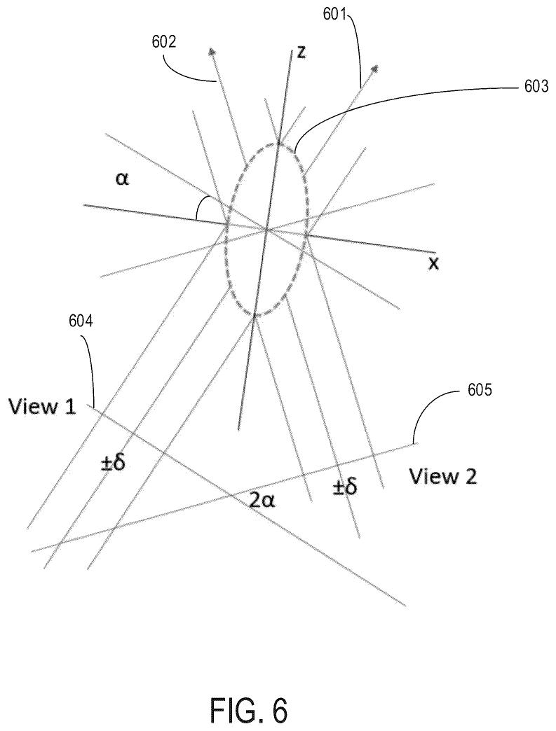

FIG. 5 illustrates another example of light beam directions relative to the sample stage. The sample stage 508 is adjusted so that the light beam 509 is directed toward sample 506 along the first axis 502 from the objective 501, and the first image is acquired. Then, the sample stage 508 is adjusted (e.g., tilted) so that the light beam 510 is directed towards the sample along the second axis 503, and the second image is acquired. The first angle 511 between the first axis 502 and the normal (Z-axis) 504 of the sample stage is the same as the second angle 512 between the second axis 503 and the normal 504 of the sample stage. Comparing to only imaging along the Z-axis, the ROI localization accuracy along the Z-axis in the overlapped region of beams 509 and 510 can be higher than the axial resolution of the beams 509 and 510 independently. As such, the ROI may be located more accurately if the two views are combined.

FIG. 6 further illustrates in 2D that by acquiring images from two different directions, the accuracy for locating the ROI is improved by reducing the uncertainty. The sample is imaged from two directions 601 and 602. Each of the first and second directions are of the same tilt angle α from the Z axis. The X-Z axes are coordinates relative to the sample stage. Region 603 represents the uncertainty in positioning of the ROI if the sample is imaged along the Z axis. The size and shape of the region 603 are determined by the imaging system’ resolution. By imaging along the 601 and 602 directions, the uncertainty in positioning along the View 1 604 and View 2 605 is ±δ. By imaging from 601 and 602 directions, the uncertainty in positioning along the X and Z axes become:

$$dZ = \frac{δ}{sin ( 2 α / 2 )} , dX = \frac{δ}{cos ( 2 α / 2 )} .$$

In another example, the first and second images are combined or merged into a 3D image stack, and the location of the ROI is determined in the merged 3D image.

In some examples, multiple first and second images are acquired from different imaging depths. The location of the ROI along the imaging axis (or beam axis) can be determined based on the signal strength. For example, the ROI may be captured in multiple sample images acquired along different imaging depths along the first axis. The ROI location along the first axis may be determined by interpolating the signals strength of the ROI in the multiple sample images.

In some examples, the ROI includes a least a target and at least a fiducial. Both the target and the fiducial are imaged in the first and second images. The coordinates of the target in the sample may be determined based on its relative location from the fiducials, evaluated from the first and second images. In some examples, one or more charged particle images of the sample may be acquired, wherein the fiducial is also imaged in the charged particle image. The coordinates of the target may be further determined based on the charged particle image. For example, stacks of the first and second sample images may be correlated with the charged particle image based on the fiducials to determine the target location.

At 314, a milling box is placed based on the location of the ROI determined at 312, and the sample is then milled based on the milling box. The sample is milled to expose the ROI. Because the ROI can be mapped accurately through the optical imaging, the ROI can be exposed by milling with high accuracy.

At 316, the milled sample is imaged. The images may be acquired during or after the milling. In one example, the sample is milled with the FIB, and FIB image(s) may be acquired during the milling process. In another example, the exposed sample surface may be imaged with optical and/or charged particle beam. For example, the milled sample may be imaged with the light/optical microscope and/or the electron beam. Images of the milled sample may be displayed to the user. In some examples, the optical image stack and the charged particle image may be registered or correlated based on fiducials imaged in the optical and charged particle images.

At 318, based on image of the milled sample acquired at 316, method 300 determines whether the ROI has been successfully exposed. If the ROI has been successfully exposed and no more milling is needed. Method 300 exits and the sample preparation process is completed. Otherwise, if further milling is needed, method 300 proceeds to 320.

At 320, method 300 determines whether the ROI location needs to be further mapped. In one example, the ROI may be remapped with higher accuracy because the signal strength of the ROI is increased after materials adjacent to the ROI is removed by milling. In another example, optical images may be taken again to determine location of another region of the ROI or a different ROI within the sample. If the ROI location needs to be determined or further mapped, method 300 proceeds to 304 to perform optical imaging from different directions. If the ROI location does not need to be remapped, method 300 proceeds to 314 to further mill the sample based on the exiting milling box, or placing another milling box based on images of the milled sample acquired at 316.

The technical effect of irradiating the sample from different directions is that the ROI is mapped in 3D with a higher resolution than the axial resolution of the optical microscopy system. The technical effect of acquiring the sample images and milling the sample while the sample is positioned on the same sample stage is that the same coordinate system may be used for imaging and milling. Further, the imaging and milling processes may be iteratively performed for better ROI mapping and monitoring the milling process in the same system.

What is claimed is:

1. A method of preparing a sample, comprising:
irradiating a sample held by a sample stage along a first axis relative to the sample with a light beam and acquiring at least a first sample image;
irradiating the sample along a second axis relative to the sample with the light beam and acquiring at least a second sample image;
determining a location of a region of interest (ROI) within the sample based on the first sample image and the second sample image; and
milling the sample held by the sample stage based on the location of the ROI.

2. The method of claim 1, wherein determining the location of the ROI based on the first sample image and the second sample image includes:
determining first coordinates of the ROI in the first sample image;
determining second coordinates of the ROI in the second sample image; and
determining the location of the ROI based on the first coordinates and the second coordinates.

3. The method of claim 2, wherein the first coordinates and the second coordinates are coordinates corresponding to the sample stage.

4. The method of claim 1, wherein the first sample image and the second sample image are fluorescent images.

5. The method of claim 4, further comprising determining the location of the ROI based on an intensity of the fluorescent images.

6. The method of claim 1, further comprising irradiating the sample along a third axis relative to the sample with the light beam and acquiring at least a third sample image, and determining location of the ROI based further on the third sample image.

7. The method of claim 1, wherein determining the location of the ROI based on the first sample image and the second sample image includes determining the location of the ROI based on orientations of the first axis and the second axis relative to the sample stage.

8. The method of claim 1, further comprising acquiring at least a charged particle image of the sample, and determining the location of the ROI further based on the charged particle image.

9. The method of claim 8, wherein determining the location of the ROI within the sample based on the first sample image and the second sample image includes determining a relative location of the ROI relative to a fiducial based on one or more of the first sample image, the second sample image, and the charged particle image; and determining the location of the ROI based on the relative location.

10. The method of claim 1, wherein milling the sample held by the sample stage based on the location of the ROI includes determining a milling angle based on the location of the ROI.

11. The method of claim 1, wherein the sample is milled with a first charged particle beam or a laser beam.

12. The method of claim 1, further comprising tilting the sample by actuating the sample stage between irradiating the sample along the first axis and irradiating the sample along the second axis.

13. The method of claim 12, wherein a first angle between the first axis and a normal of the sample stage and the second angle between the second axis and the normal of the sample stage is the same.

14. The method of claim 1, wherein determining the location the ROI within the sample based on the first sample image and the second sample image includes merging the first image and the second image and determining the location of the ROI in the merged image.

15. The method of claim 1, wherein the sample is a frozen biological sample, and the milled sample is a lamella to be analyzed in a transmission electron microscope.

16. The method of claim 1, wherein irradiating the sample along the first axis relative to the sample with the light beam and acquiring at least the first sample image includes acquiring multiple sample images at different imaging depths with the light beam irradiated at the first axis, wherein irradiating the sample along the second axis relative to the sample with the light beam and acquiring at least the second sample image includes acquiring multiple sample images at different imaging depths with the light beam irradiated at the second axis, and wherein determining the location of the ROI based on the first sample image and the second sample image includes determining the location of the ROI based on the multiple sample images acquired with the light beam irradiated along the first axis and the multiple sample images acquired with the light beam irradiated along the second axis.

17. A microscopy system, comprising:
a sample chamber;
a sample stage positioned in the sample chamber;
a light source for generating a light beam;
a detector;
a controller including a processor and a non-transitory memory for storing computer readable instructions, by executing the computer readable instructions in the processor, the microscopy system is configured to:
irradiate a sample held by the sample stage along a first axis relative to the sample with the light beam and acquire at least a first sample image via the detector;
irradiate the sample along a second axis relative to the sample with the light beam and acquire at least a second sample image via the detector;
determine a location of a region of interest (ROI) within the sample based on the first sample image and the second sample image; and
mill the sample held by the sample stage based on the location of the ROI.

18. The microscopy system of claim 17, further comprising: a first charged particle source for generating a first charged particle beam and a second particle source for generating a second charged particle beam, and the microscopy system is further configured to: acquire an image of the ROI with the second charged particle beam after milling the sample with the first charged particle beam.

19. The microscopy system of claim 17, wherein the microscopy system is further configured to: acquire a third sample image by irradiating the milled sample with the light beam; update the location of the ROI based on the third sample image; and mill the sample based on the updated location of the ROI.

20. The microscopy system of claim 17, further comprising an actuator for actuating the sample stage, and the microscopy system is further configured to tilt the sample to irradiate the sample along the second axis after irradiating the sample along the first axis.
